(19) United States
(12) Patent Application Publication
(10) Pub. No.: US 2007/0097227 A1
(43) Pub. Date: May 3, 2007

(54) Solid-state imaging device

(75) Inventor: Fumitoshi Toyokawa, Miyagi (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/585,822

(22) Filed: Oct. 25, 2006

(30) Foreign Application Priority Data
Oct. 26, 2005 (JP) P2005-311358

(51) Int. Cl. H04N 5/228

(52) U.S. Cl. 348/222.1

(57) ABSTRACT

A solid-state imaging device includes a large number of pixel portions each of which includes a photo diode 30. A part of the large number of pixel portions are pixel portions for detecting a black level. The pixel portions for detecting the black level are scattered in a region where the large number of pixel portions are arranged.

### BACKGROUND OF THE INVENTION

1. Field of the Invention

This invention relates to a solid-state imaging device having a large number of pixel portions that include photoelectric conversion elements.

2. Description of the Related Art

JP 2004-15712 A discloses a digital camera including an optical black (OB) portion in an ineffective pixel region that does not contribute to capturing of an image by the solid-state imaging device. JP 2004-15712 A corrects a black level by subtracting signals obtained from the OB portion from signals obtained from an effective pixel region, which contributes to the capturing of the image.

Generally, signal levels of solid-state imaging devices vary, which result from process variation peculiar to an element step in manufacturing. Also, layout of the pixel portions and a peripheral circuit portion causes a distribution of signal levels. Therefore, even if the OB portion is provided only in the ineffective pixel region and an average dark signal, which is calculated only from this ineffective pixel region, is subtracted from the signals obtained from the effective pixel region, black levels of the signals from the effective pixel region cannot be corrected to a sufficient degree. That is, a uniform image is not obtained and the image quality deteriorates unless the black level is corrected with the variation of the dark signal level and the distribution of the dark signal level being considered.

### SUMMARY OF THE INVENTION

The invention has been made under these circumstances and provides a solid-state imaging device, which can improve the image quality by effectively correcting the black level.

According to an aspect of the invention, a solid-state imaging device includes a large number of pixel portions each of which includes a photoelectric conversion element. A part of the large number of pixel portions are pixel portions for detecting a black level. The pixel portions for detecting the black level are scattered in a region where the large number of pixel portions are arranged.

Also, each of the large number of pixel portions may be formed with an opening that limits light falling on the corresponding photoelectric conversion element. The openings of the pixel portions for detecting the black level are closed.

Also, each of the large number pixel portions may include a micro lens for collecting light onto the corresponding photoelectric conversion element. The pixel portions for detecting the black level don't include the micro lens.

Each of the large number of pixel portions may include an intra-layer lens for collecting light onto the corresponding photoelectric conversion element. The pixel portions for detecting the black level don't include the intra-layer lens.

Also, each of the pixel portions for detecting the black level may further include a file disposed above the corresponding opening. The film is made of a material used for forming a peripheral circuit.

Also, the solid-state imaging device includes an output amplifier that outputs a signal in accordance with charges, which are read and transferred from the photoelectric conversion elements. Number of the pixel portions for detecting the black level, which are arranged in a region close to the output amplifier, is larger than number of the pixel portions for detecting the black level, which are arranged in the other regions.

Also, the large number of pixel portions may be divided into a plurality of blocks. Each of the blocks contains at least one pixel portion for detecting the block level.

According to the above configuration, a solid-state imaging device can improve the image quality by effectively correcting the black level.

### BRIEF DESCRIPTION OF THE DRAWINGS

FIG. 1 is a schematic plan view for explaining a solid-state imaging device according to an embodiment of the invention.

FIG. 2 is a schematic section view taken along a line A-A in FIG. 1.

FIG. 3 is a schematic section view illustrating a modified example of a pixel portion for detecting a black level.

FIG. 4 is a schematic section view illustrating another modified example of the pixel portion for detecting the black level.

### DETAILED DESCRIPTION OF EMBODIMENTS OF THE INVENTION

Embodiments of the invention will now be described with reference to the drawings.

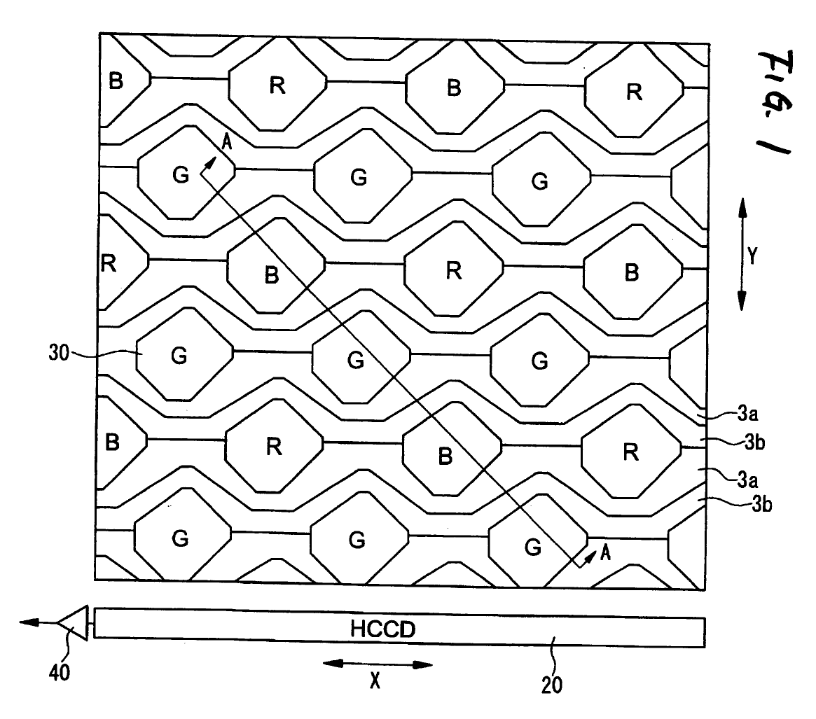

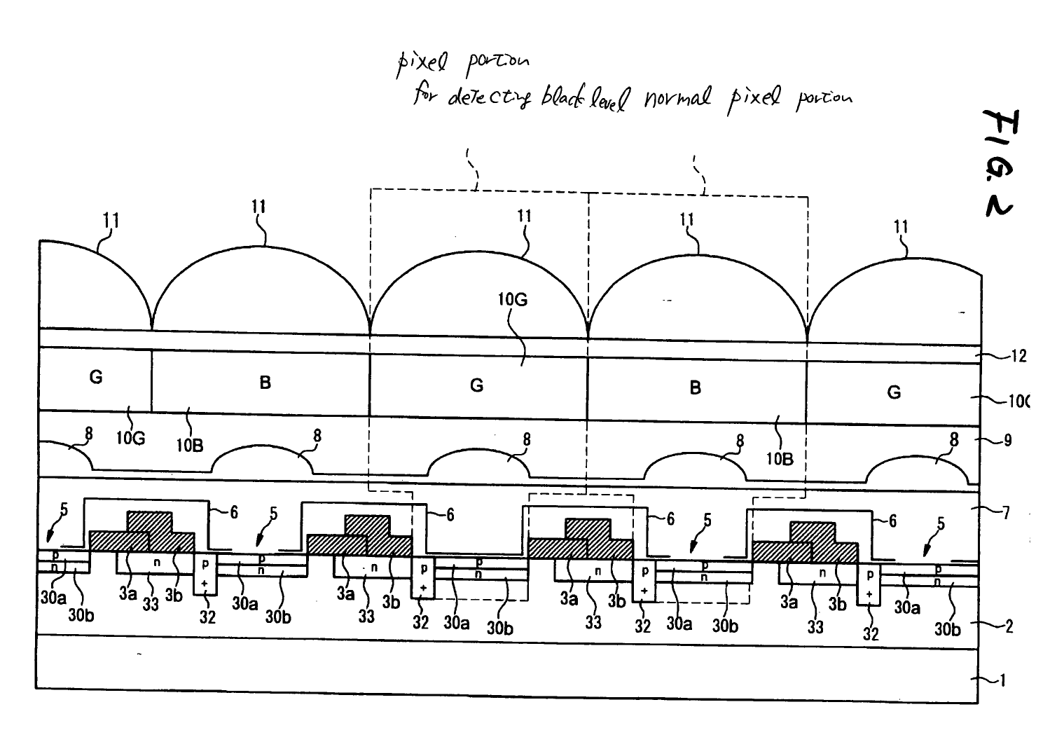

FIG. 1 is a schematic plan view for explaining a solid-state imaging device according to an embodiment of the invention. FIG. 2 is a schematic section view taken along a line A-A in FIG. 1.

The solid-state imaging device shown in FIGS. 1 and 2 is formed with a large number of photodiodes 30, which serve as photoelectric conversion elements, on the surface of an n-type silicon substrate 1. Charge transfer portions (not shown) for transferring signal charges, which are generated by the photodiodes 30, in a column direction (a direction Y in FIG. 1) are formed to meander among plural photodiode columns constituted by plural photodiodes 30 arranged in the column direction.

The Charge transfer portions include plural charge transfer channels 33, charge transfer electrodes 3 (a first electrode 3a and a second electrode 3b) and charge read-out region. The charge transfer channels 33 are formed on the surface of a silicon substrate 1 in the column direction so as to correspond to the plural photodiode columns. The charge transfer electrodes 3 are formed above the charge transfer channel and has a two-layer electrode structure. The charge read-out regions are used to read out the charges generated by the photodiodes 30 to the charge transfer channels 33. The charge transfer electrodes 3 meander as a whole in a row direction (a direction X in FIG. 1) among the plural photodiode rows constituted by the plural photodiodes 30 arranged in the row direction. The charge transfer electrodes 3 may be of a single-layer electrode structure.

As shown in FIG. 2, a p-well layer 2 is formed on the surface of the silicon substrate 1, p-regions 30a are formed on the surface of the p-well layer 2 and n-regions 30b are formed below the p-regions 30a. The p-regions 30a and the n-regions 30b form the photo diodes 30. Signal charges generated by the photodiodes 30 are accumulated in the n-regions 30b.

Each of the charge transfer channels 33 of n-region is formed on a right side of the p-region 30a so as to be slightly separate from each other. The charge read-out regions (not shown) are formed in the p-well layer 2 between the n-regions 30b and the charge transfer channels 33.

A gate oxide film (not shown) is formed on the surface of the silicon substrate 1. The first electrodes 3a and the second electrodes 3b are formed on the charge read-out regions and on the charge transfer channels 33, via the gate oxide film. The first electrodes 3a and the second electrodes 3b are insulated from each other by an insulating film (not shown) Each channel stop 32 of p⁺-region is formed on a right side of the vertical transfer channel 33 so isolate the adjacent photodiodes 30 from each other.

Light-shielding films 6 are formed on the electric charge-transfer electrodes 3. Openings 5 are formed in the light-shielding films 6 to limit a range where light falls on the photodiodes 30. The charge transfer electrodes 3 and the light-shielding films 6 are embedded in a transparent insulating film 7. Intra-layer lenses 8 are formed on the insulating film 7 to collect light onto the openings 5 of the photodiodes 30. A flattening layer 9 is formed on the intra-layer lenses 8. Color filters 10G for transmitting green light, color filters 10B for transmitting blue light and color filters (not shown in FIG. 2) for transmitting red light are formed on the flattening layer 9. In FIG. 1, the photodiodes 30 having the color filters 10G formed thereabove are denoted by reference signs “G”, the photodiodes 30 having color filters 10B formed thereabove are denoted by reference signs “B”, and the photodiodes 30 having color filters for transmitting red light, formed thereabove are denoted by reference signs “R.”

A flattening layer 12 of an insulating and transparent resin is formed on the color filters 10G, 10B, 10R. Micro lenses 11 are formed on the flattening layer 12 to collect light onto the openings 5 of the photodiodes 30.

In the solid-state imaging device according to this embodiment, signal charges generated by the photodiode 30 are accumulated in the n-regions 30b. The signal charges accumulated in the n-regions 30b are transferred in the column direction through the charge transfer channels 33. The transferred signal charges are further transferred in the row direction (the direction X in FIG. 1) through a charge transfer passage (HCCD) 20. An output amplifier 40 outputs color signals in response to the transferred signal charges.

The solid-state imaging device according to this embodiment includes a large number of pixel portions each of which includes the photodiode 30 and the opening 5, the intra-layer lens 8, the color filter 10 and the micro lens 11, which are formed on or above the photo diode 30. A part of the large number of pixel portions are pixel portions for detecting a dark signal level (black level). The pixel portions for detecting the black level are not concentrated in the peripheral portions of a region where the large number of pixel portions are arranged, as in JP 2004-15712 A. To the contrary, the pixel portions for detecting the black level are scattered in the region where the large number of pixel portions are arranged. Of the large number of pixel portions, pixel portions except the pixel portions for detecting the black level may be referred to as “normal pixel portions.”

For example, the large number of pixel portions may be divided into plural blocks and a single pixel portion for detecting the black level may be provided in each block. It is noted that number of the pixel portion for detecting the black level provided in each block is not limited to one, and that plural pixel portions for detecting the black level may be provided in each block. For example, the solid-state imaging device having million pixel portions may be divided into 100 blocks in units of blocks each containing 100×100 pixel portions. In this case, a single pixel portion for detecting the black level may be provided in each of 100 blocks. Signals obtained from the pixel portions for detecting the black level are subtracted from signals obtained from the normal pixel portions of the blocks, to correct the black level. Thereby, the black level can be corrected with the variation of the dark signal level and the distribution of the dark signal level being considered. Accordingly, a uniform image can be achieved and the image quality can be improved.

Generally, an image pickup device such as a digital camera equipped with a solid-state imaging device executes a pixel defective correction process on a defective photo diode so as to interpolate a signal of the defective photo diode by using signals obtained from surrounding photo diodes. However, a signal obtained from the pixel portion for detecting the black level is not a favorable signal for forming image data. Therefore, it is also necessary to correct this signal by the defective pixel correction process. Therefore, the number of the pixel portions for detecting the black level is required to be in a range where the defective pixel correction process can correct the signals obtained from the pixel portions for detecting the black level.

When the solid-state imaging device captures an image with exposing for long time, the black level of the photodiodes 30, which is close to the output amplifier 40, may become greater than the black level of other photodiodes 30 due to affection of hot electron light emission from the output amplifier 40 shown in FIG. 1. Then, number of the pixel portions for detecting the black level, which are shown in FIGS. 2 to 4 and are close to the output amplifier 40, may be larger than number of the pixel portions for detecting the black level, which are disposed in the other regions. Thereby, the black level can be corrected more accurately. For example, the large number of pixel portions may be divided into two each transversely and longitudinally, that is, may be divided into four blocks. Among these four blocks, the block closest to the output amplifier 40 may contain larger number of the pixel portions for detecting the black level, and the other blocks may contain smaller number of the pixel portions for detecting the black level than those in the block closest to the output amplifier 40.

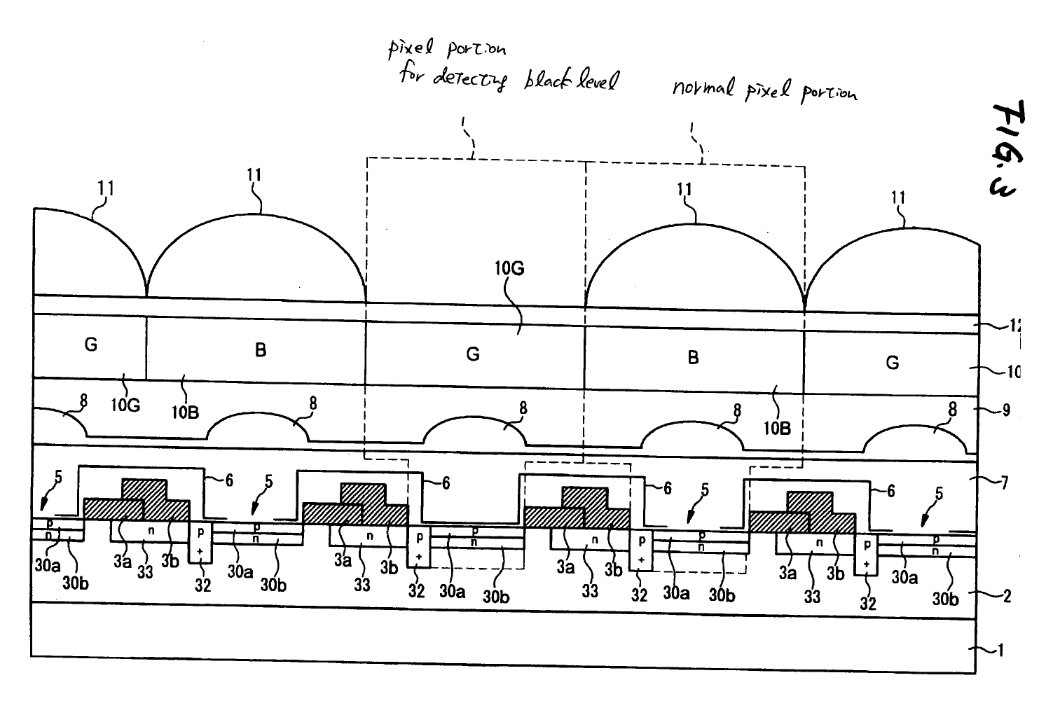

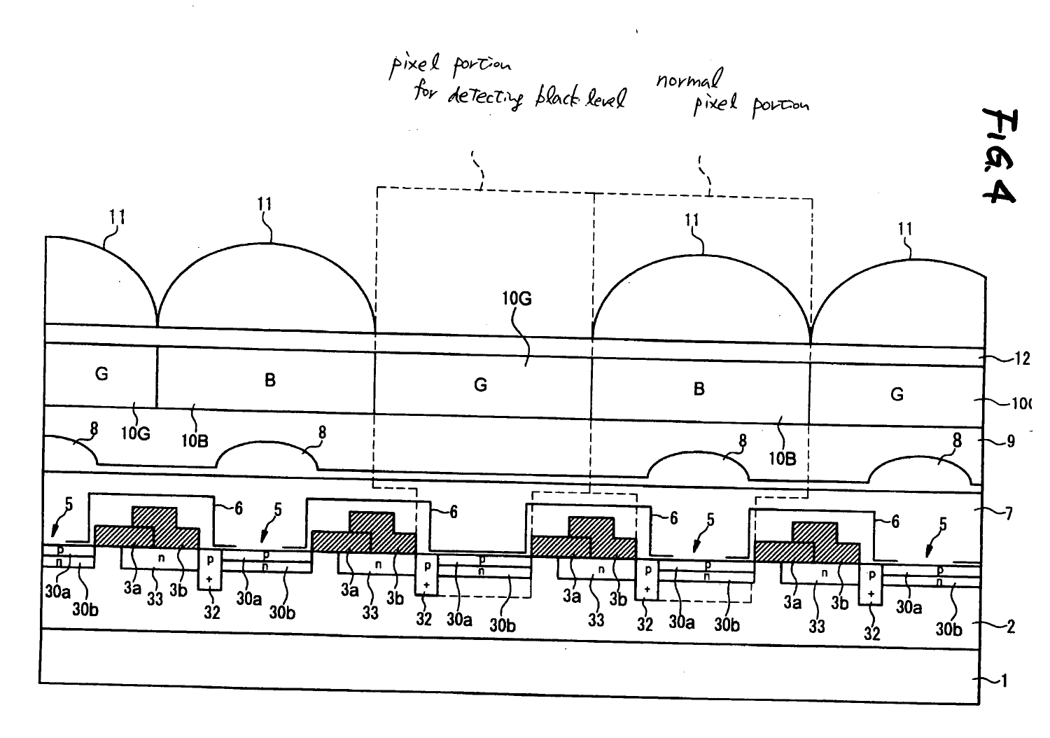

In order to detect the black level, it is necessary that no light falls on the photodiode 30 (the pixel portion for detecting the black level). As shown in FIG. 2, for example, a pixel portion in which the opening 5 contained in the normal pixel portion is closed may be used as the pixel portion for detecting the black level. Or, as shown in FIG. 3, a pixel portion in which the opening 5 contained in the normal pixel portion is closed and no micro lens 11 is formed may be used as the pixel portion for detecting the black level. Or, as shown in FIG. 4, a pixel portion in which the opening 5 contained in the normal pixel portion is closed, and neither the micro lens 11 nor the intra-layer lens 8 is formed may be used as the pixel portion for detecting the black level. By not forming the micro lens 11 and the intra-layer lens 8, no incident light is collected onto a place where the opening 5 is formed. This structure makes it possible to more effectively prevent light from falling on the photodiode 30. In the structure shown in FIG. 2, the intra-layer lens 8 may be omitted to obtain the same effect.

In the steps of producing the solid-state imaging device shown in FIGS. 2 to 4, a material such as aluminum for constituting a peripheral circuit is once formed on the light-shielding film 6 at the time of forming the peripheral circuit. Usually, the aluminum film on the light-shielding film 6 is removed at the time of forming the peripheral circuit. The aluminum film, however, may be left above the photodiode 30 only that is included in the pixel portions for detecting the black level. This structure further improves the light-shielding performance.

According to the solid-state imaging device of this embodiment, a part of the pixel portions, which are originally designed to be formed, are utilized as the pixel portions for detecting the black level. Therefore, it is possible to obtain the above effect without increasing the number of production steps or without increasing the manufacturing cost.

Although the embodiment has dealt with a solid-state imaging device of the CCD type, the invention can similarly be applied to the solid-state imaging device of the MOS type. Further, the arrangement of photodiodes 30 is not limited to that shown in FIG. 1, but may be, for example, a square lattice arrangement.

What is claimed is:

1. A solid-state imaging device comprising:
a large number of pixel portions each of which includes a photoelectric conversion element, wherein:
a part of the large number of pixel portions are pixel portions for detecting a black level, and
the pixel portions for detecting the black level are scattered in a region where the large number of pixel portions are arranged.

2. The solid-state imaging device according to claim 1, wherein:
each of the large number of pixel portions is formed with an opening that limits light falling on the corresponding photoelectric conversion element, and
the openings of the pixel portions for detecting the black level are closed.

3. The solid-state imaging device according to claim 2, wherein:
each of the large number pixel portions includes a micro lens for collecting light onto the corresponding photoelectric conversion element, and
the pixel portions for detecting the black level don't comprise the micro lens.

4. The solid-state imaging device according to claim 2, wherein:
each of the large number of pixel portions includes an intra-layer lens for collecting light onto the corresponding photoelectric conversion element, and
the pixel portions for detecting the black level don't comprise the intra-layer lens.

5. The solid-state imaging device according to claim 3, wherein:
each of the large number of pixel portions includes an intra-layer lens for collecting light onto the corresponding photoelectric conversion element, and the pixel portions for detecting the black level don't comprise the intra-layer lens.

6. The solid-state imaging device according to claim 2, wherein each of the pixel portions for detecting the black level further comprises a file disposed above the corresponding opening, the film made of a material used for forming a peripheral circuit.

7. The solid-state imaging device according to claim 3, wherein each of the pixel portions for detecting the black level further comprises a file disposed above the corresponding opening, the film made of a material used for forming a peripheral circuit.

8. The solid-state imaging device according to claim 4, wherein each of the pixel portions for detecting the black level further comprises a file disposed above the corresponding opening, the film made of a material used for forming a peripheral circuit.

9. The solid-state imaging device according to claim 5, wherein each of the pixel portions for detecting the black level further comprises a file disposed above the corresponding opening, the film made of a material used for forming a peripheral circuit.

10. The solid-state imaging device according to claim 1, further comprising:
an output amplifier that outputs a signal in accordance with charges, which are read and transferred from the photoelectric conversion elements, wherein:
number of the pixel portions for detecting the black level, which are arranged in a region close to the output amplifier, is larger than number of the pixel portions for detecting the black level, which are arranged in the other regions.

11. The solid-state imaging device according to claim 2, further comprising:
an output amplifier that outputs a signal in accordance with charges, which are read and transferred from the photoelectric conversion elements, wherein:
number of the pixel portions for detecting the black level, which are arranged in a region close to the output amplifier, is larger than number of the pixel portions for detecting the black level, which are arranged in the other regions.

12. The solid-state imaging device according to claim 3, further comprising:
an output amplifier that outputs a signal in accordance with charges, which are read and transferred from the photoelectric conversion elements, wherein:
number of the pixel portions for detecting the black level, which are arranged in a region close to the output amplifier, is larger than number of the pixel portions for detecting the black level, which are arranged in the other regions.

13. The solid-state imaging device according to claim 4, further comprising:
an output amplifier that outputs a signal in accordance with charges, which are read and transferred from the photoelectric conversion elements, wherein:
number of the pixel portions for detecting the black level, which are arranged in a region close to the output amplifier, is larger than number of the pixel portions for detecting the black level, which are arranged in the other regions.

14. The solid-state imaging device according to claim 6, further comprising:
an output amplifier that outputs a signal in accordance with charges, which are read and transferred from the photoelectric conversion elements, wherein:
number of the pixel portions for detecting the black level, which are arranged in a region close to the output amplifier, is larger than number of the pixel portions for detecting the black level, which are arranged in the other regions.

15. The solid-state imaging device according to claim 1, wherein:
the large number of pixel portions are divided into a plurality of blocks, and
each of the blocks contains at least one pixel portion for detecting the block level.
